(19) United States
(12) Patent Application Publication
(10) Pub. No.: US 2019/0013811 A1
(43) Pub. Date: Jan. 10, 2019

(54) RECONFIGURABLE CIRCUIT, RECONFIGURABLE CIRCUIT SYSTEM, AND METHOD FOR OPERATING RECONFIGURABLE CIRCUIT

(71) Applicant: NEC Corporation, Minato-ku, Tokyo (JP)

(72) Inventors: Yukihide TSUJI, Tokyo (JP); Toshitsugu SAKAMOTO, Tokyo (JP); Makoto MIYAMURA, Tokyo (JP); Xu BAI, Tokyo (JP); Ayuka TADA, Tokyo (JP); Ryusuke NEBASHI, Tokyo (JP)

(73) Assignee: NEC Corporation, Minato-ku, Tokyo (JP)

(21) Appl. No.: 16/066,738

(22) PCT Filed: Jan. 18, 2017
(86) PCT No.: PCT/JP2017/001525

§ 371 Date: Jun. 28, 2018

(30) Foreign Application Priority Data
Jan. 20, 2016 (JP) 2016-008495

(51) Int. Cl. H03K 19/177; G11C 13/00; H01L 27/24

(52) U.S. Cl. CPC H03K 19/1776; G11C 13/0069; H01L 27/2481; G11C 2213/79; G11C 13/003; G11C 2213/71; H01L 27/2436

(57) ABSTRACT

The purpose of the present invention is to increase the efficiency with which silicon on a chip is used, and to easily reduce the size of a logic cell. To accomplish the purpose, this reconfigurable circuit includes: a logic memory unit configured from a resistance change element, and positioned distributed into at least two units; a logic unit for referencing the logic memory unit and performing logical operations; and a signal path switching unit for receiving the results of the logical operation of the logic unit and outputting said results to the outside. The logic memory part and the signal path switching part constitute part of a crossbar switching circuit, and share write wiring to the resistance change element.

### TECHNICAL FIELD

The present invention relates to a reconfigurable circuit, a reconfigurable circuit system, and a method for operating a reconfigurable circuit.

### BACKGROUND ART

A programmable logic integrated circuit (reconfigurable circuit) has a feature that setting information of an inside is rewritten and thereby various logic circuits can be reconfigured.

Commonly, a reconfigurable circuit includes a logic unit that is a memory reference-type logical operation unit including a look up table (LUT) and a flip-flop, an input/output signal switching unit (hereinafter, referred to as an IMUX) for the logic unit, and a signal path switching unit (hereinafter, referred to as an SMUX) between the logic units.

A circuit size (i.e. the number of configurable logics) of a reconfigurable circuit can be adjusted by designing a configurable logic block (CLB or logic cell) having a size to some extent including a logic unit, an IMUX, and an SMUX, and adjacently disposing the designed logic cells in such a way as to be mutually connectable. Specifically, when the number of logic cells adjacently disposed is adjusted, a circuit size can be adjusted, and therefore semiconductor chips including reconfigurable circuits having different circuit sizes can be easily produced according to customer needs. Note that an IMUX that is a signal switching unit and an SMUX that is a signal path switching unit are implemented by using, for example, a static random access memory (SRAM) and an SRAM switch including a pass transistor. Recently, the above-described technique is widely being used in fields such as preparation of a prototype, image processing and communication.

PTL 1 and PTL 2 disclose a technique capable of reducing a chip area and power consumption by configuring an IMUX and an SMUX with a resistance change element. When a resistance change element is used as a switch on a reconfigurable circuit, all switches on the circuit are always applied with voltage. Therefore, compared with a case of use as a memory, higher reliability is required.

PTL 3 and PTL 4 disclose a complementary-type (1T2R) structure using one transistor and two paired resistance change elements instead of a switch cell of a 1T1R structure in which one transistor and one resistance change element are set. Such a switch cell using a resistance change element is used as a switch cell (multiplexer) such as an IMUX and an SMUX that switches a signal by using a crossbar configuration.

In a crossbar configuration, a switch cell is disposed in each cross-point vicinity of signal wiring (RV) in a vertical direction and signal wiring (RH) in a lateral direction. Further, the switch cell is also connected to two write control lines (SV and GH) for controlling a selection transistor (Tr.) in order to cause a resistance change element at a cross-point to be ON/OFF.

NPL 1 discloses a configuration of a reconfigurable circuit that optimizes an area/power/delay for a benchmark reconfiguration target circuit (e.g. an MCNC 20 benchmark).

### CITATION LIST

### Patent Literature

[PTL 1] Japanese Registered Patent Publication No. 4356542
[PTL 2] International Publication No. WO 2012/043502
[PTL 3] International Publication No. WO 2013/190742
[PTL 4] International Publication No. WO 2014/030393
[PTL 5] Japanese Unexamined Patent Application Publication No. 2010-170572
[PTL 6] Japanese Translation of PCT International Application Publication No. 2008-539597
[PTL 7] Japanese Unexamined Patent Application Publication No. 2006-120702

### Non Patent Literature

[NPL 1] “Architecture of Reconfigurable-Logic Cell Array with Atom Switch: Cluster Size & Routing Fabrics”, Xu Bai, et.al., Proceedings of the 2015 ACM/SIGDA International Symposium on Field-Programmable Gate Arrays, pp. 269, (2015)

### SUMMARY OF THE INVENTION

### Technical Problem

In recent years, with an increase in element performance of a resistance change element, a write current value and voltage have been reduced. Therefore, not only a high breakdown voltage transistor such as a 3.3 V transistor and a 1.8 V transistor but also a logical operation core transistor having a small occupied area disposed on a silicon substrate have been able to perform write control for a resistance change element.

A size (height) of a logic cell has been defined by a transistor (a height of a switch cell). However, when a height of a switch cell is small, usage efficiency of a silicon substrate inside a logic cell decreases when a height of the logic cell is restricted by a wiring density in which a wiring density restricts a height of a logic cell. With a pitch of a height determined by a transistor size, switch cells are arranged (an array cycle of a transistor and a cycle of a wiring pattern are changed), and thereby a space for semiconductor element formation can be created in upper and lower regions of a height direction of a crossbar switch region. However, in such a structure, wiring is complex, and further in a space, a driver control line of a crossbar switch circuit runs vertically using lower-layer wiring close to a silicon substrate and exists in a narrow pitch including a power supply line. Therefore, a dead space is generated. A logic cell having such a dead space may become disadvantageous in reduction of a size of the logic cell.

An object of the present invention is to provide a reconfigurable circuit capable of increasing silicon usage efficiency on a chip and easily reducing a size of a logic cell.

### Solution to the Problem

A reconfigurable circuit according to one aspect of the present invention includes: a logic memory unit including a resistance change element and being disposed by distribution into at least two units; a logic unit that refers to the logic memory unit and executes a logical operation; and a signal path switching unit that receives a result of the logical operation of the logic unit and outputs the result to an outside, the logic memory unit and the signal path switching unit configuring a crossbar switch circuit and sharing write wiring to the resistance change element.

In a reconfigurable circuit system according to another aspect of the present invention, the reconfigurable circuits according to one aspect of the present invention are disposed by being connected to one another in parallel.

In a method for operating a reconfigurable circuit according to yet another aspect of the present invention, a logic unit refers to a logic memory unit including a resistance change element and being disposed by distribution into at least two units and executes a logical operation; and a signal path switching unit receives a result of the logical operation of the logic unit and outputs the result to an outside, the logic memory unit and the signal path switching unit configuring a crossbar switch circuit and sharing write wiring to the resistance change element.

### Advantageous Effects of the Invention

It is possible that local high-densification of wiring is reduced, silicon usage efficiency on a chip is increased, and thereby a size of a logic cell is easily reduced.

### BRIEF DESCRIPTION OF DRAWINGS

FIG. 1(a) is a schematic diagram illustrating a resistance change element according to an example embodiment of the present invention.

FIG. 1(b) is a schematic diagram in which FIG. 1(a) is simplified. FIG. 1(c) is a table representing a voltage for changing a resistance of the resistance change element according to the example embodiment of the present invention.

FIG. 2(a) is a schematic diagram illustrating a switch cell according to the example embodiment of the present invention. FIG. 2(b) is a schematic diagram illustrating how the switch cell according to the example embodiment of the present invention is disposed in a cross-point cell. FIG. 2(c) is a schematic diagram illustrating a wiring layout of the switch cell according to the example embodiment of the present invention.

FIG. 3 is a schematic diagram illustrating a crossbar switch circuit according to the example embodiment of the present invention.

FIG. 4 is a schematic diagram illustrating an appearance of the crossbar switch circuit according to the example embodiment of the present invention.

FIG. 5 is a block diagram illustrating a configuration of a logic cell according to the example embodiment of the present invention.

FIG. 6 is a schematic diagram illustrating a configuration of a logic block according to the example embodiment of the present invention.

FIG. 7 is a schematic diagram illustrating connection among logic cells according to the example embodiment of the present invention.

FIG. 8 is a block diagram illustrating a configuration of a crossbar switch circuit according to the example embodiment of the present invention.

FIG. 9 is a block diagram illustrating a configuration of a logic cell according to the example embodiment of the present invention.

FIG. 10 is a schematic diagram illustrating a wiring layout of a highest density wiring region.

FIG. 11 is a block diagram illustrating generation of a dead space in a logic cell.

FIG. 12 is a block diagram illustrating a configuration of a logic cell according to the example embodiment of the present invention.

FIG. 13 is a block diagram for illustrating a principle of a reconfigurable circuit according to the example embodiment of the present invention.

### EXAMPLE EMBODIMENT

Hereinafter, with reference to the drawings, an example embodiment of the present invention will be described in detail. Note that, in order to avoid complication due to repeated descriptions, the same or equivalent portion in respective figures is assigned with the same reference sign, and therefore description is omitted as appropriate.

### First Example Embodiment

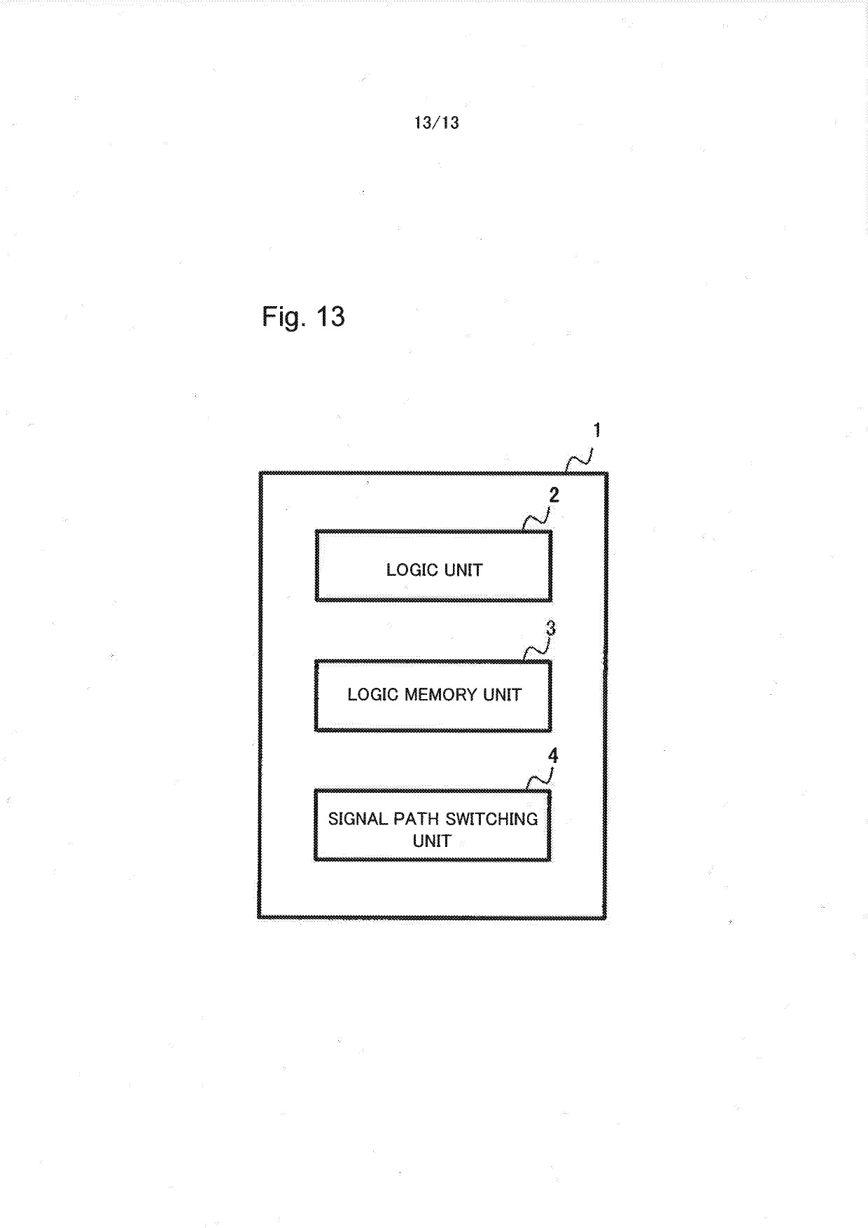

FIG. 13 is a block diagram of a reconfigurable circuit for describing the present example embodiment.

As illustrated in FIG. 13, a reconfigurable circuit 1 includes a logic unit 2, a logic memory unit 3, and a signal path switching unit 4.

The logic unit 2 is a logical operation unit capable of executing a logical operation by referring to the logic memory unit 3 and includes, for example, a plurality of N-input look up table, a flip-flop, and the like. The logic memory unit 3 is, for example, a memory including a resistance change element. The signal path switching unit 4 includes a resistance change element, similarly to the logic memory unit 3. Further, the logic memory unit 3 and the signal path switching unit 4 share a resistance change element. Further, write wiring of the resistance change element included in the logic memory unit 3 and the resistance change element included in the signal path switching unit 4 is shared between the logic memory unit 3 and the signal path switching unit 4 in a crossbar switch circuit.

Hereinafter, a configuration of the present example embodiment will be described in detail.

### [Configuration of a Resistance Change Element]

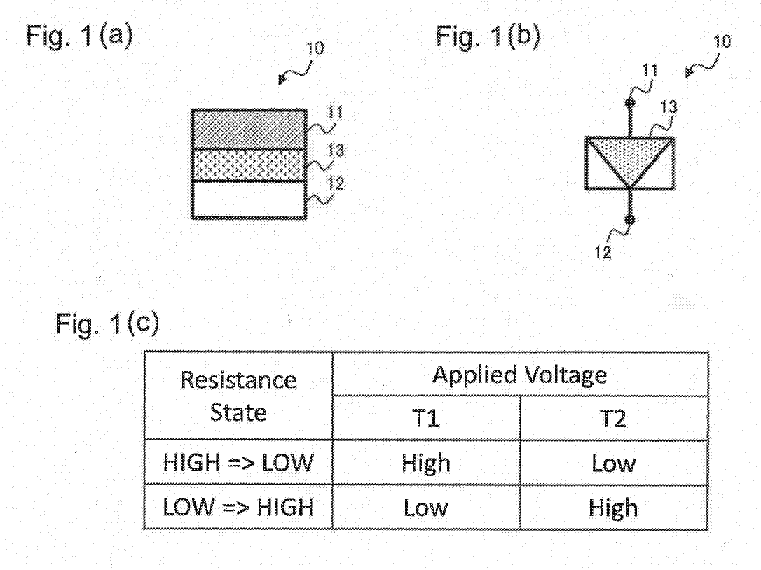

FIG. 1 is a schematic diagram illustrating one example of a resistance change element according to the present example embodiment, FIG. 1(a) is a schematic diagram illustrating a resistance change element, FIG. 1(b) is a symbolic expression in which FIG. 1(a) is simplified, and FIG. 1(c) is a table representing a voltage for changing a resistance of the resistance change element.

As illustrated in FIG. 1(a), the resistance change element 10 includes a first wiring layer 11, a second wiring layer 12, and a solid electrolytic layer 13. Specifically, the resistance change element 10 includes the solid electrolytic layer 13 between the first wiring layer 11 and the second wiring layer 12.

FIG. 1(c) is a table representing a correspondence relation between a resistance value of the resistance change element 10 and a voltage. As illustrated in FIG. 1(c), a resistance value of the resistance change element 10 is changed by applying a forward bias or a reverse bias to both ends of the resistance change element 10. Specifically, a resistance value of the resistance change element 10 is switched from a high resistance state (OFF-state) to a low resistance state (ON-state) when a bias of the first wiring layer 11 is at a high level and a bias of the second wiring layer 12 is at a low level. On the other hand, a resistance value of the resistance change element 10 is switched from a low resistance state to a high resistance state when a bias of the first wiring layer 11 is at a low level and a bias of the second wiring layer 12 is at a high level. Note that, a ratio of resistance values of a low resistance state and a high resistance state of the resistance change element 10 is, for example, equal to or larger than 10⁵.

For the above-described resistance change element 10, used is, but not specifically limited to, a resistance change element such as a resistance random access memory (ReRAM) using a transition metal oxide, a NanoBridge (a registered trademark) using an ion conductor, and the like in which it is possible that a resistance is changed by applying a voltage equal to or larger than a certain level for a predetermined time or more and the changed resistance is maintained. Further, the resistance change element 10 may be a resistance change element including two bipolar resistance change elements having polarity in an application direction of a voltage for changing a resistance. In this case, the resistance change element 10 is preferably configured in such a way that two bipolar resistance change elements are oppositely connected in series and a switch (transistor) is disposed at a connection point of two switches. The reason is that the resistance element 10 having such a configuration has high disturbance resistance upon causing signals to continuously pass and use the signals. Further, the resistance change element 10 may be a resistance change element using transfer of metallic ions and electrochemical reaction in a solid (ion conductor) where ions freely moves by application of an electric field.

The resistance change element 10 as described above achieves a large resistance change amount and therefore can be used as a switch element capable of discriminating whether a signal passes or does not pass between electrodes. For specific description, as illustrated in FIG. 1, the resistance change element 10 includes the solid electrolytic layer 13 and the first wiring layer 11 and the second wiring layer 12 making contact with the solid electrolytic layer 13 and being disposed to be opposed to each other. In the case of the resistance change element 10 having such a configuration, the solid electrolytic layer 13 receives metallic ions from the first wiring layer 11 but does not receive metallic ions from the second wiring layer 12. Therefore, the resistance change element 10 can control a conduction state between the first wiring layer 11 and the second wiring layer 12, since a resistance value of the solid electrolytic layer 13 is changed through a change in polarity of an applied voltage.

### [Configuration of a Switch Cell]

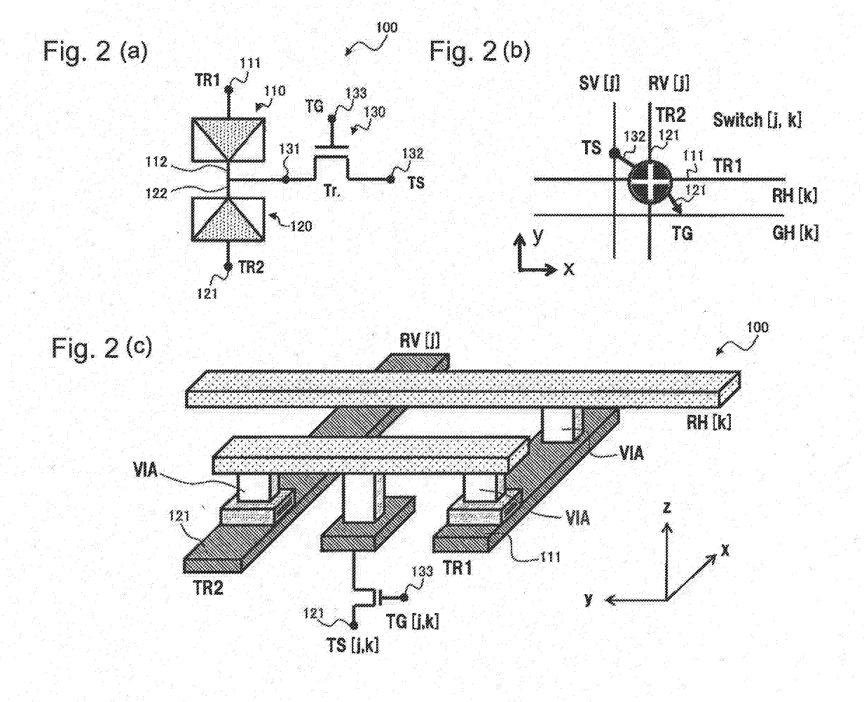

FIG. 2 is a schematic diagram illustrating a configuration of a switch cell according to the present example embodiment, and FIG. 2(a) is a schematic diagram illustrating a switch cell including two resistance change elements and a transistor.

A switch cell 100 includes at least a first resistance element 110, a second resistance change element 120, and a selection transistor 130. In other words, the switch cell 100 is a switch cell having a complementary (1T2R) structure using one transistor and two paired resistance change elements.

The first resistance change element 110 is a resistance change element including a first electrode 111 and a second electrode 112 and includes a configuration similar to the configuration of the resistance change element 10 illustrated in FIG. 1. In other words, a resistance value of the first resistance change element 110 is changed according to a voltage applied to the first electrode 111 and the second electrode 112.

The second resistance change element 120 is a resistance change element including a first electrode 121 and a second electrode 122 and includes a configuration similar to the configuration of the resistance change element 10 illustrated in FIG. 1. In other words, a resistance value of the second resistance change element 120 is changed according to a voltage applied to the first electrode 121 and the second electrode 122.

The selection transistor 130 can include, for example, a common transistor.

As illustrated in FIG. 2(a), the second electrode 112 of the first resistance change element 110 and the second electrode 122 of the second resistance change element 120 are connected to each other. Further, the second electrode 112 of the first resistance change element 110 and the second electrode 122 of the second resistance change element 120 are connected to one diffusion layer (a source or drain) 131 of the selection transistor 130.

FIG. 2(b) is a schematic diagram illustrating a switch cell disposed as a cross-point cell for signal switching.

As illustrated in FIG. 2(b), the switch cell 100 is used as a switch for a crossbar switch. Specifically, the switch cell 100 is disposed in a cross-point vicinity of a signal line RV[j] that is wiring in a y direction and a signal line RH[k] that is wiring of an x direction in FIG. 2(b). Further, the first electrode 111 of the first resistance change element 110 is connected to the signal line RH[k], and the first electrode 121 of the second resistance change element 120 is connected to the signal line RV[j]. In other words, the signal line RV[j] and the signal line RH[k] each are connected to an electrode that is not shared between the first resistance change element 110 and the second resistance change element 120.

Further, a gate electrode 133 of the selection transistor 130 is connected to a write control line GH[k], and a diffusion layer (a drain or source) 132 on a side where either the first resistance change element 110 or the second resistance change element 120 is not connected is connected to a write control line SV[j]. While being specifically described later, the write control line GH[k] and the write control line SV[j] are wired independently of the signal line RH[k] and the signal line RV[j] and are shared with another switch existing in a wiring direction.

FIG. 2(c) illustrates a stereoscopic schematic diagram of the switch cell 100 illustrated in FIG. 2(a) and FIG. 2(b).

As illustrated in FIG. 2(c), the signal line RH[k] is located in a +z direction of the first electrode 111 of the first resistance change element 110. Further, the signal line RH[k] and the first electrode 111 of the first resistance change element 110 are electrically connected via a VIA.

The signal line RV[j] and the first electrode 121 of the second resistance change element 120 are electrically connected in the same xy plane. Note that the first electrode 111 of the first resistance change element 110 and the first electrode 121 of the second resistance change element 120 are located in the same xy plane.

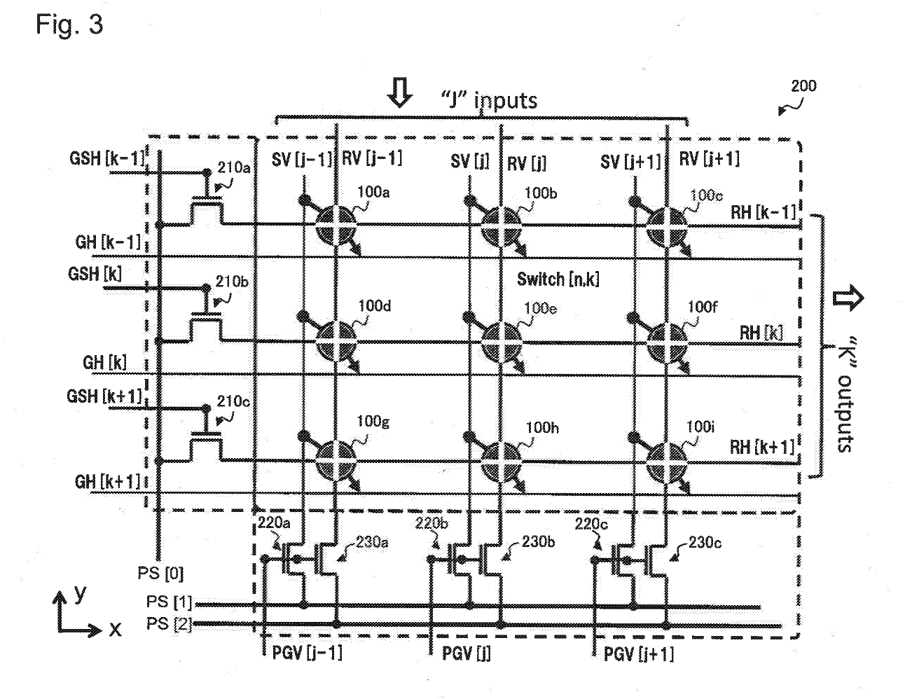

FIG. 3 is a schematic diagram illustrating a crossbar switch circuit 200 according to the present example embodiment. As illustrated in FIG. 3, the crossbar switch circuit 200 is a crossbar circuit that performs k outputs for j inputs.

The crossbar switch circuit 200 includes a switch cell 100a, a switch cell 100b, a switch cell 100c, a switch cell 100d, a switch cell 100e, a switch cell 100f, a switch cell 100g, a switch cell 100h, and a switch cell 100i. The switch cell 100a to the switch cell 100i include a configuration similar to the configuration of the above-described switch cell 100.

As illustrated in FIG. 3, the switch cell 100a, the switch cell 100b, and the switch cell 100c share a write control line GH[k−1] and a signal line RH[k−1] that are wiring of an x direction. The write control line GH[k−1] and the signal line RH[k−1] each are independent wiring. Further, the signal line RH[k−1] is connected to one diffusion layer of a first control transistor 210a connected to the switch cell 100a, the switch cell 100b, and the switch cell 100c. Herein, the other diffusion layer of the first control transistor 210a is connected to a power source line PS[0], and a gate electrode is connected to a write control line GSH[k−1].

The switch cell 100d, the switch cell 100e, and the switch cell 100f share a write control line GH[k] and a signal line RH[k] that are wiring of an x direction. The write control line GH[k] and the signal line RH[k] each are independent wiring. Further, the signal line RH[k] is connected to one diffusion layer of a first control transistor 210b connected to the switch cell 100d, the switch cell 100e, and the switch cell 100f. Herein, the other diffusion layer of the first control transistor 210b is connected to the power source line PS[0], and a gate electrode is connected to a write control line GSH[k].

The switch cell 100g, the switch cell 100h, and the switch cell 100i share a write control line GH[k+1] and a signal line RH[k+1] that are wiring of an x direction. The write control line GH[k+1] and the signal line RH[k+1] each are independent wiring. Further, the signal line RH[k+1] is connected to one diffusion layer of a first control transistor 210c connected to the switch cell 100g, the switch cell 100h, and the switch cell 100i. Herein, the other diffusion layer of the first control transistor 210c is connected to the power source line PS[0], and a gate electrode is connected to a write control line GSH[k+1].

The switch cell 100a, the switch cell 100d, and the switch cell 100g l share a write control line SV[j−1] and a signal line RV[j−1] that are wiring of a y direction. The write control line SV[j−1] and the signal line RV[j−1] each are independent wiring. Further, the write control line SV[j−1] is connected to one diffusion layer of a second control transistor 220a connected to the switch cell 100a, the switch cell 100d, and the switch cell 100g. Herein, the other diffusion layer of the second control transistor 220a is connected to a power source line PS[1], and a gate electrode is connected to a driver control line PGV[j−1]. Further, the signal line RV[j−1] is connected to one diffusion layer of a third control transistor 230a connected to the switch cell 100a, the switch cell 100d, a and the switch cell 100g. Herein, the other diffusion layer of the third control transistor 230a is connected to a power source line PS[2], and a gate electrode is connected to the driver control line PGV[j−1].

The switch cell 100b, the switch cell 100e, and the switch cell 100h share a write control line SV[j] and a signal line RV[j] that are wiring of a y direction. The write control line SV[j] and the signal line RV[j] each are independent wiring. Further, the write control line SV[j] is connected to one diffusion layer of a second control transistor 220b connected to the switch cell 100b, the switch cell 100e, and the switch cell 100h. Herein, the other diffusion layer of the second control transistor 220b is connected to the power source line PS[1], and a gate electrode is connected to a driver control line PGV[j]. Further, the signal line RV[j] is connected to one diffusion layer of a third control transistor 230b connected to the switch cell 100b, the switch cell 100e, and the switch cell 100h. Herein, the other diffusion layer of the third control transistor 230b is connected to the power source line PS[2], and a gate electrode is connected to the driver control line PGV[j].

The switch cell 100c, the switch cell 100f, and the switch cell 100i share a write control line signal line SV[j+1] and a signal line RV[j+1]. The write control line SV[j+1] and the signal line RV[j+1] each are independent wiring. Further, the write control line SV[j+1] is connected to one diffusion layer of a second control transistor 220c connected to the switch cell 100c, the switch cell 100f, and the switch cell 100i. Herein, the other diffusion layer of the second control transistor 220c is connected to the power source line PS[1], and a gate electrode is connected to a driver control line PGV[j+1]. Further, the signal line RV[j+1] is connected to one diffusion layer of a third control transistor 230c connected to the switch cell 100c, the switch cell 100f, and the switch cell 100i. Herein, the other diffusion layer of the third control transistor 230c is connected to the power source line PS[2], and a gate electrode is connected to the driver control line PGV[j+1].

Note that, the write control line GSH[k−1] is wiring used to change a resistance of a switch element included in the switch cell 100a, the switch cell 100b, and the switch cell 100c. Further, the write control wiring GSH[k−1] is connected to a gate voltage of the control transistor 210a.

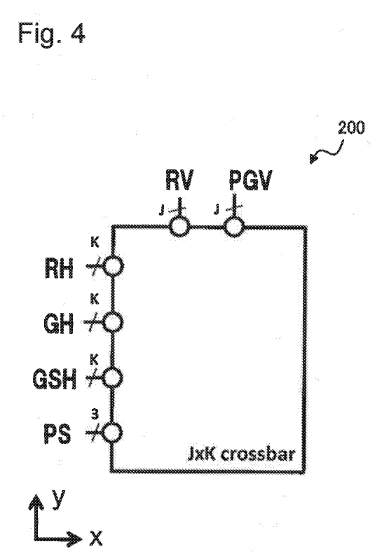

FIG. 4 is a schematic diagram illustrating an appearance of an interface of the crossbar switch circuit 200. As illustrated in FIG. 4, a signal line RV and a driver control line PGV are disposed on one side corresponding to an x direction. Further, a signal line RH, a write control line GH, a write control line GSH, and a power source line PS are disposed on the other side corresponding to a y direction. Note that an appearance diagram of the crossbar switch illustrated in FIG. 4 is an illustrative example and therefore does not limit the present invention.

### [Configuration of a Reconfigurable Circuit]

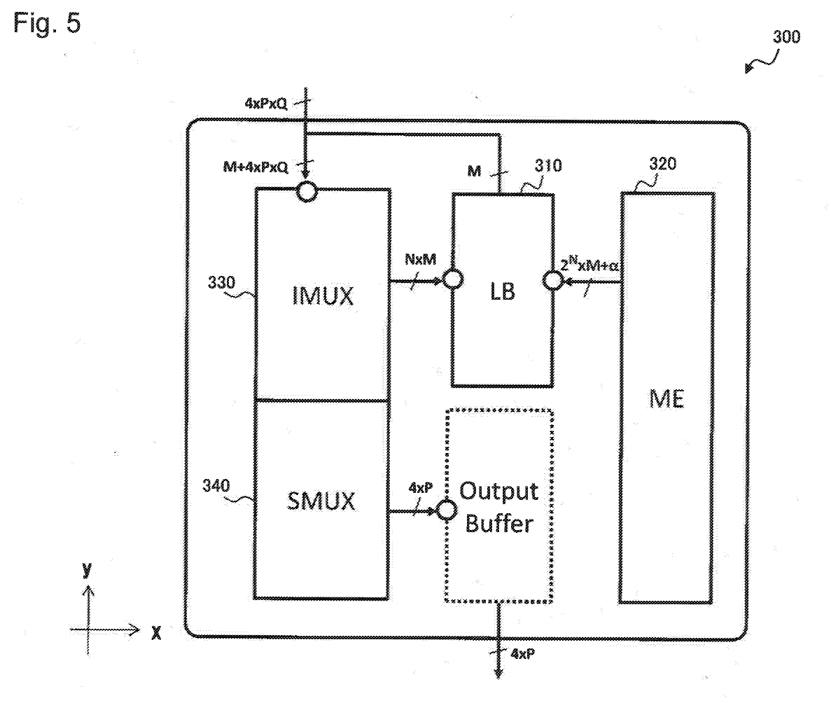

FIG. 5 illustrates a block diagram of a logic cell that is a basic configuration of a reconfigurable circuit. As illustrated in FIG. 5, a logic cell 300 includes a logic unit (LB) 310, a logic memory unit (ME) 320, an IMUX 330, and an SMUX 340.

The logic unit 310 includes at least a plurality (e.g. M) of N-input look up tables (LUTs). The N-input represents that N control signals are input from the IMUX 330. Therefore, the logic unit 310 includes, when including M look up tables, input ports for N×M IMUXs 330. Further, M N-input look up tables included in the logic unit 310 each include one output port, and therefore the logic unit 310 includes M output ports.

The logic memory unit 320 includes (2̂N) memories when the logic unit 310 includes an N-input look up table. In this case, each of the (2̂N) memories included in the logic memory unit 320 is connected to the logic unit 310. Therefore, the logic unit 310 includes, when including M look up tables, input ports for ((2̂N)×M) logic memory units 320. Note that the logic memory unit 320 includes, for example, α memories used in input/output switching and the like to a flip-flop and the like and therefore includes input ports for ((2̂N)×M)+α logic memory units 320 in total.

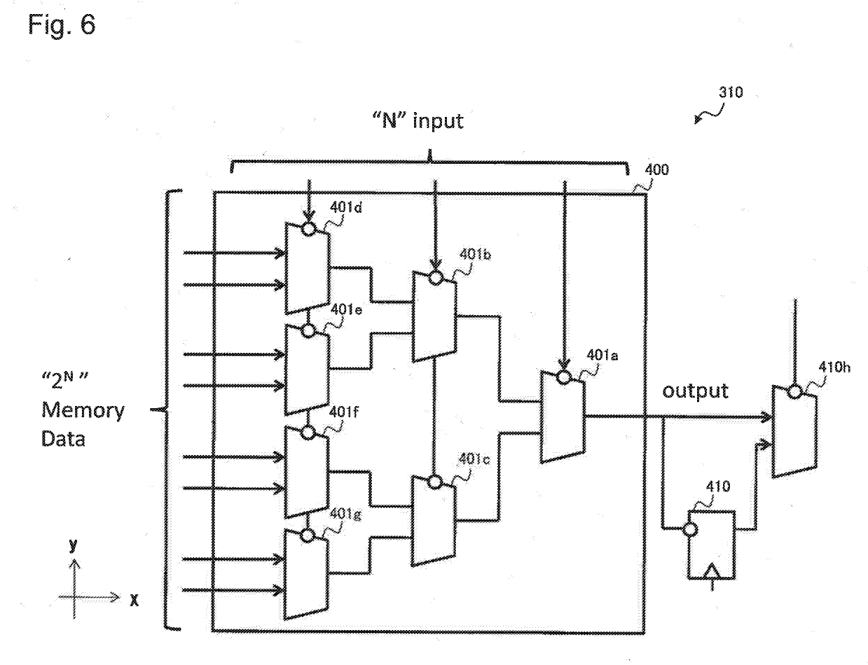

FIG. 6 is a schematic diagram illustrating one example of a look up table included in the logic unit 310. Note that while a look up table 400 illustrated in FIG. 6 will be described as being N=3 in order to ease description, this is an illustrative example and does not limit the present invention. In the present example embodiment, the logic unit 310 can use look up tables of any input number.

The look up table 400 includes a multiplexer 401a, a multiplexer 401b, a multiplexer 401c, a multiplexer 401d, a multiplexer 401e, a multiplexer 401f, and a multiplexer 401g.

The multiplexer 401a to the multiplexer 401g each include two input ports. Input ports of the multiplexer 401a are connected to the multiplexer 401b and the multiplexer 401c. Input ports of the multiplexer 401b are connected to the multiplexer 401d and the multiplexer 401e. Input ports of the multiplexer 401c are connected to the multiplexer 401f and the multiplexer 401g.

The multiplexer 401a, the multiplexer 401b, and the multiplexer 401d each receive a signal from the IMUX 330.

An input port of each of the multiplexer 401d, the multiplexer 401e, the multiplexer 401f, and the multiplexer 401g is connected to a memory included in the logic memory unit 320. In other words, when N=3, the look up table 400 is connected to 2³=8 memories.

As illustrated in FIG. 6, in the look up table 400, the multiplexer 401a outputs one signal in response to signals received from the logic memory unit 320 and the IMUX 330. The multiplexer 401a inputs the output signal, for example, to the multiplexer 401h and the flip-flop 410. Note that the flip-flop 410 outputs a signal in response to the received signal and inputs the output signal to the multiplexer 401h.

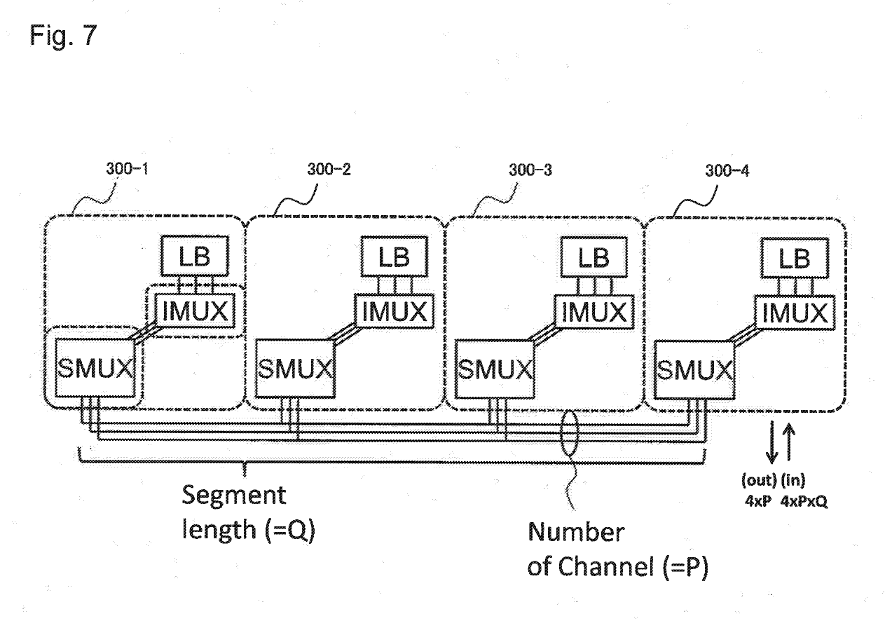

FIG. 7 is a schematic diagram illustrating connection among logic cells.

Specifically, FIG. 7 illustrates a case where in a crossbar configuration, a first logic cell 300-1, a second logic cell 300-2, a third logic cell 300-3, and a fourth logic cell 300-4 are connected. Hereinafter, with reference to FIG. 5 and FIG. 7, connection among logic cells will be described.

As illustrated in FIG. 7, logic cells each connected via P channels, and a segment length (an interval covering the logic cells) is Q.

Therefore, in the case of FIG. 7, four logic cells are connected, and therefore the number of output ports of the SMUX 340 is (4×P) in total. On the other hand, M outputs from M look up tables included in the logic unit 310 and (4×P×Q) outputs from an outside of the logic cell 300 are input to the SMUX 340. Therefore, the number of output ports of the SMUX 340 is (M+4×P×Q) in total.

The number of output ports of the IMUX 330 is (N×M) when the logic unit 310 includes M N-input look up tables. Further, the number of input ports of the IMUX 330 is (M+4×P×Q), similarly to the SMUX 340.

The IMUX 330 and the SMUX 340 include input ports of the same number, and therefore as illustrated in FIG. 5, in a direction where an input signal travels, one crossbar circuit can be configured by connecting the IMUX 330 and the SMUX 340.

The logic memory unit 320 can be mounted in the same process without using another memory by using a resistance change-type switch cell (crossbar switch) used as a switch for the IMUX 330 and the SMUX 340. In other words, the logic memory unit 320, the IMUX 330, and the SMUX 340 can be common.

Note that the above-described configuration is an illustrative example, and a segment length and the number of channels may be different between respective logic cells. Specifically, the number of channels may be different depending on positions and directions of logic cells in a reconfigurable circuit, and a segment length may be different depending on channels.

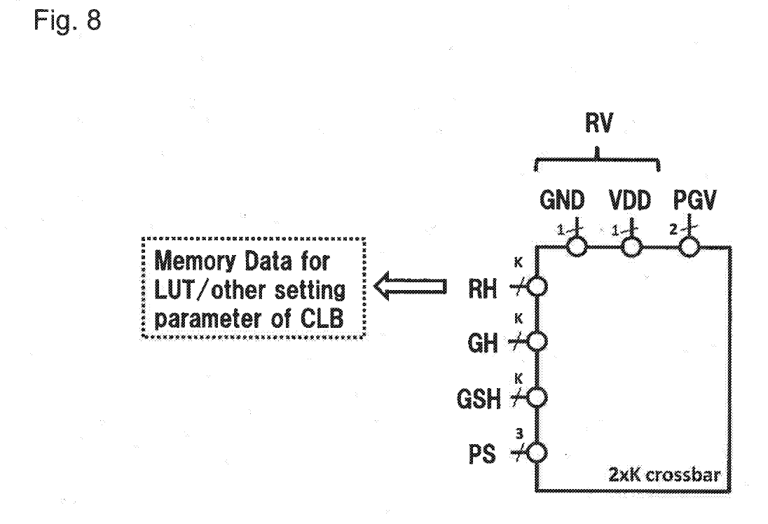

FIG. 8 is a schematic diagram illustrating an appearance of a crossbar switch circuit used in the logic memory unit 320 according to the present example embodiment.

As illustrated in FIG. 8, in a crossbar switch circuit, a power source line VDD and ground wiring (GND) disposed on a side corresponding to an x direction are set as inputs, and a signal line RH disposed on a side corresponding to a y direction is connected to an input port of the logic memory unit 220.

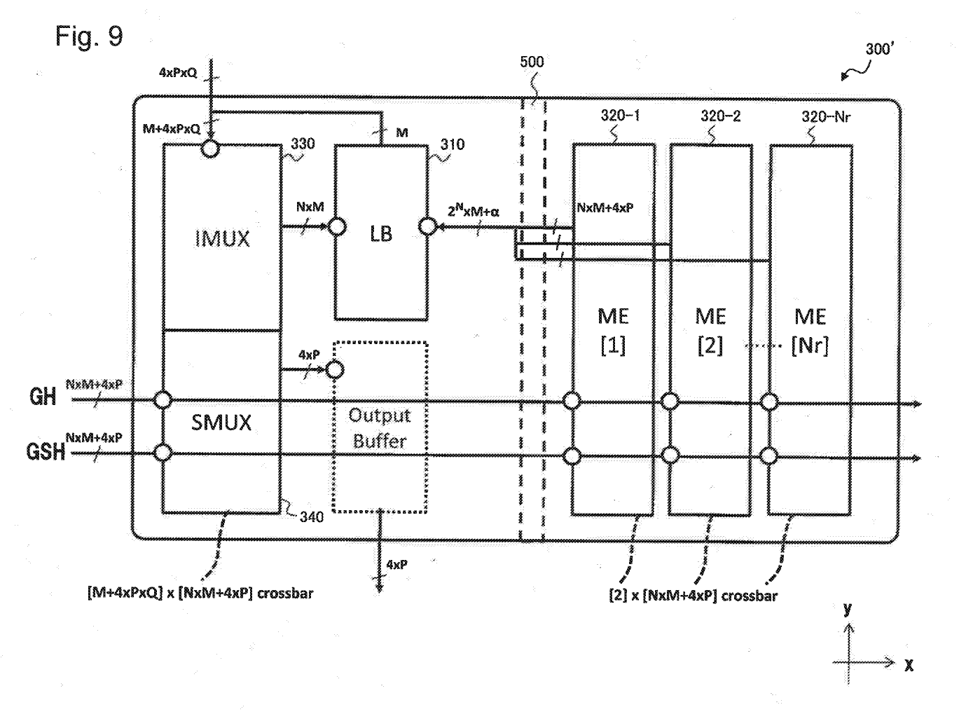

FIG. 9 is a block diagram illustrating a logic cell including internal wiring for a logical operation and write wiring. Hereinafter, with reference to FIG. 9, a wiring density in the logic cell will be described.

As illustrated in FIG. 9, a logic cell 300′ includes a logic unit 310, logic memory units 320-1 to 320-Nr, an IMUX 330, and an SMUX 340. In other words, in the logic cell 300′, a memory is disposed by being divided into Nr units.

Two factors for defining sizes of height/lateral directions of a logic cell mutually connectable by being arranged in parallel as illustrated in FIG. 9 will be described.

A first factor is a size of a selection transistor in a switch cell to write a resistance change element. For specific description, a size of a switch cell is defined by a size of a high breakdown voltage transistor in a technical node of 65 nm when, for example, in order to rewrite a resistance change element, a voltage resistance of equal to or larger than 4V is needed and a current of approximately 1 mA needs to flow. Specifically, a size of a high breakdown voltage transistor is, for example, 3.2 μm×0.76 μm (a longitudinal direction=a height of a switch cell=a Y direction). A minimally necessary size of a height direction of a crossbar switch including the IMUX 330 and the SMUX 340 is (a height of a switch cell)×(the number of output ports of the IMUX 330+the number of output ports of the SMUX 340). Therefore, a minimally necessary size is defined, and therefore this becomes a first factor for restricting a size of a height direction of a logic cell (factor 1).

A second factor is a wiring density in a logic cell.

In order to share a write signal line of a resistance change element, a crossbar switch of the logic memory unit 320 needs to be aligned in height with a crossbar switch including the IMUX 330 and the SMUX 340 by setting the number of cells to be (the number of output ports of the IMUX 330+the number of output ports of the SMUX 340). Therefore, crossbar switches are disposed by being arranged in a lateral (x) direction for a rounded-up integer (Nr) of ((2̂N)×M)+α)/(the number of output ports of the IMUX 330+the number of output ports of the SMUX 340).

As illustrated in FIG. 9, in the logic cell 300′, wiring is made from the logic unit 310 to each of the logic memory units 320-1 to 320-Nr, and therefore a highest density wiring region 500 in which a wiring density is highest exists between the logic unit 310 and the logic memory unit 320-1.

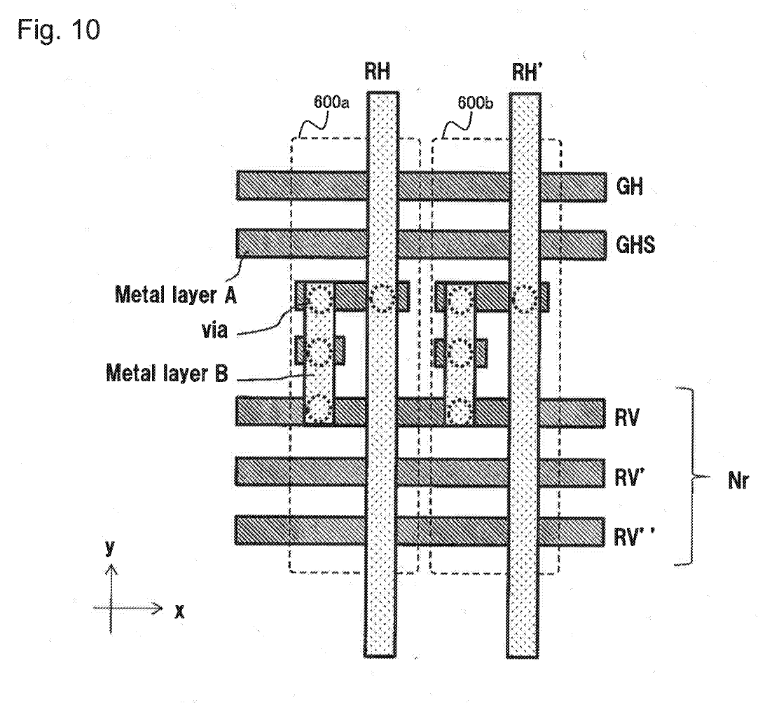

FIG. 10 is a schematic diagram illustrating a configuration of a switch cell. FIG. 10 illustrates a switch cell 600a and a switch cell 600b.

In the highest density wiring region 500, as illustrated in FIG. 10, it is necessary to ensure, as a wiring space of a height (Y) direction, (Nr+4) grids for each of the switch cell 600a and the switch cell 600b. Herein, Nr is represented by a signal line RV, a signal line RV′, and a signal line RV″. Therefore, when it is assumed that a wiring pitch is P (=0.24 μm (in the case of a 65 nm technical node)), P×(Nr+4)×(the number of output ports of an IMUX+the number of output ports of an SMUX) is a second factor for defining a height direction of a logic cell (factor 2).

A height of a logic cell is defined by a magnitude relation between the above-described factor 1 and factor 2. A size of a lateral direction of a logic cell can be determined by fixing a height direction and disposing a circuit in such a way as to reduce a size of the lateral direction as much as possible. Note that factor 1 is simplified as “a height of a switch cell determined by a transistor size” and factor 2 is simplified as “P×(Nr+4)”. In other words, a magnitude relation between factors 1 and 2 is determined by magnitudes of “a height of a switch determined by a transistor size” and “P×(Nr+4)”.

Recently, as described above, a height of a switch cell has been reduced, and therefore a wiring density restricts a height of a logic cell.

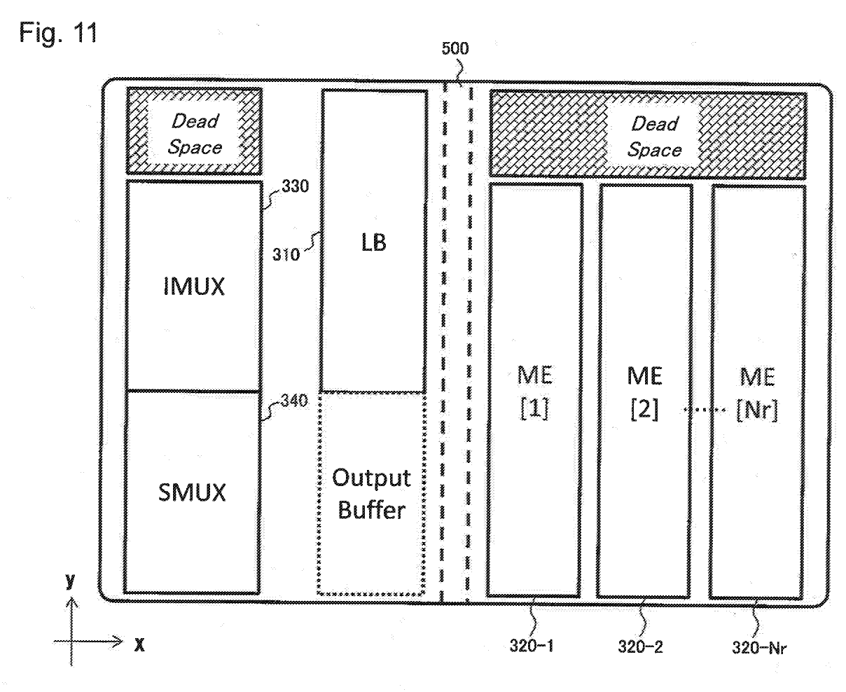

When a height of a logic cell is restricted by a wiring density in the logic cell, usage efficiency of a silicon substrate in the logic cell is decreased. Switch cells are arranged in a pitch of a height direction (y direction) determined by a transistor size (by changing an alignment period of a transistor and a period of a wiring pattern), and thereby a space for semiconductor element formation can be formed in upper and lower regions of a height direction of a crossbar switch. However, such a space becomes a dead space and also wiring is complicated. FIG. 11 illustrates that a dead space produces an adverse effect in reduction of a size of a logic cell.

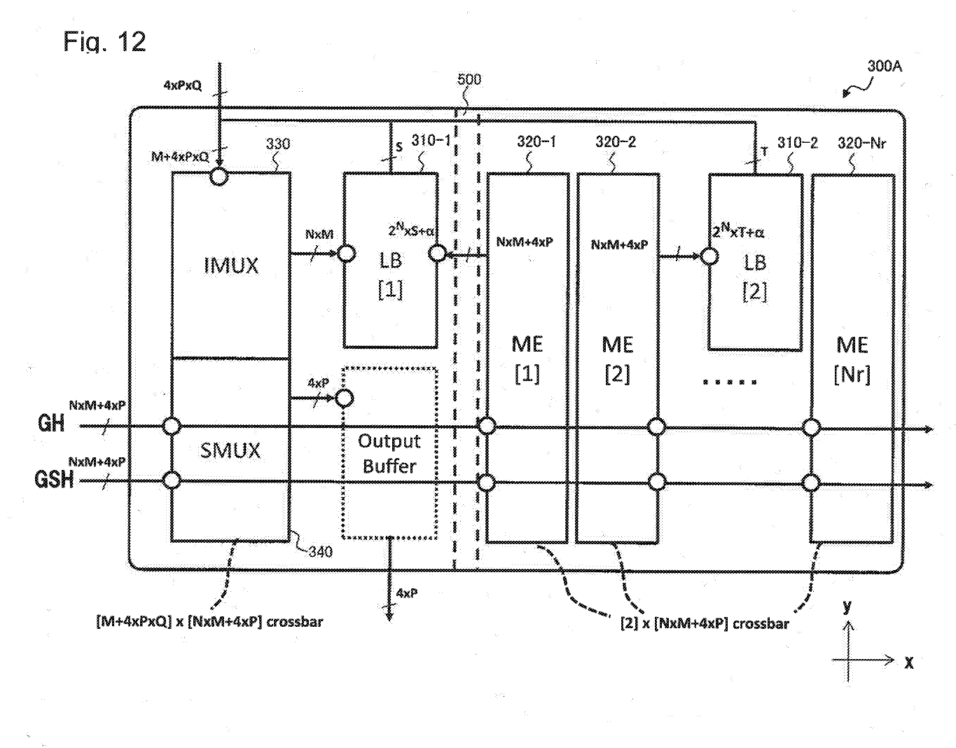

FIG. 12 is a schematic diagram illustrating an example of distributed disposition in the logic cell according to the present example embodiment.

As illustrated in FIG. 12, a logic cell 300 includes a logic unit 310-1, a logic unit 310-2, logic memory units 320-1 to 320-Nr, an IMUX 330, and an SMUX 340. In the logic cell 300, a write control line GH and a write control line GSH are shared between the logic memory units 320-1 to 320-Nr and the SMUX 340.

The logic unit 310-1 includes S look up tables. In other words, the logic unit 310-1 includes ((2̂N)×S)+α) inputs. The logic unit 310-2 includes T look up tables. In other words, the logic unit 310-1 includes ((2̂N)×T)+α) inputs.

Further, the logic unit 310-1 and the logic unit 310-2 are disposed by distribution in the logic cell. In this case, S signal lines are connected to the IMUX 330 from the logic unit 310-1, and T signal lines are connected to the IMUX 330 from the logic unit 310-2. S+T=M is satisfied.

Of the logic memory units 320-1 to 320-Nr, the logic memory unit 320-1 corresponding to the logic unit 310-1 is disposed adjacently to the logic unit 310-1. Further, of the logic memory units 320-1 to 320-Nr, the logic memory unit 320-2 corresponding to the logic unit 310-2 is disposed adjacently to the logic unit 310-2.

Herein, the write control line GH and the write control line GSH are preferably shared with a crossbar switch including the IMUX 330 and the SMUX 340, without specific limitation. Thereby, an increase in the numbers of write control lines and write decoder circuits can be suppressed to a minimum level.

### [Comparison of Wiring Densities]

A wiring density of a common highest density wiring region 500 as illustrated in FIG. 11 is as follows with respect to one logic cell.

P×[(Nr+4)×(the number of output ports of an IMUX+the number of output ports of an SMUX)]/an area of a logic cell (A)

In contrast, a wiring density of the highest density wiring region 500 according to the present invention as illustrated in FIG. 12 is as follows.

P×[(1+4)×(the number of output ports of an IMUX+the number of output ports of an SMUX)+T]/an area of a logic cell (B)

The number of look up tables of the logic unit 310-1 is S, and the number of look up tables of the logic unit 310-2 is T. In other words, S+T=M is satisfied. Further, a logic memory unit is divided in such a way as to satisfy ((2̂N)×S)≤(N×M+4×P) and ((2̂N)×T)≤(N×M+4×P). N−1>1, N>1, and M>T, and therefore the following relation is established.

(A)−(B)∝{(Nr−1)×(N×M+4×P)+T}>{(Nr−1)×(N×M)−T}>0

As described above, the present invention can reduce a wiring density, and therefore usage efficiency of silicon on a chip is increased, whereby a size of the logic cell 300 can be easily reduced. Further, each crossbar in the logic cell 300 is disposed by distribution while sharing of a write line is maintained. Therefore, in each crossbar, there are no increase in the number of write lines and no increase in the number of accompanying decoder circuits in association with distributed disposition of a logic unit.

Note that the logic cell illustrated in FIG. 12 includes two logic units that are the logic unit 310-1 and the logic unit 310-2, but this matter is an illustrative example and does not limit the number of divisions of a logic unit. The number of divisions may be equal to or larger than 3, and a similar effect may be produced by such division.

Note that a logic memory unit disposed by distribution is preferably disposed in an x-axis inversion symmetry manner. Thereby, positions of a logic unit, a crossbar of a logic memory unit, and an input/output port are easily matched and more linear wiring is made possible, resulting in improvements in delay and power performance.

Further, when logical operation information is mapped on the logic memory unit 310 and a switch of the IMUX 330 (a resistance change element is written and a logical operation circuit is configured on a reconfigurable circuit), a logical operation existing on a critical path preferably uses preferentially a logic unit close to the IMUX 330. When such a configuration is employed, an operation frequency can be increased, compared with a mapping pattern where allocation is made to a logic memory unit at random even when the same logical operation is executed.

### Second Example Embodiment

As a second example embodiment, a four-input look up table will be described as an example.

In a four-input look up table, when a benchmark reconfigurable circuit (e.g. an MCNC 20) is optimized in area, power, and delay, it is necessary that the number of look up tables be 4, a segment length of CLBs be 4, and the number of connection channels be 4.

Therefore, switch cell alignment for 4×4=16 units is necessary for output of an SMUX crossbar. Further, switch cell alignment for 4×4=16 units is necessary for output of an IMUX crossbar. Therefore, with regard to a height (Y direction) of a logic cell, a height of a switch cell for at least 16+16=32 units is necessary.

On the other hand, for a memory of the logic memory unit 320, at least (2̂4)×4=64 units are needed. When thereto, the number α of memories used for input/output switching and the like to a flip-flop and the like is added, Nr=(64+α)/32>2 (i.e. Nr≥3 which is an integer) is established.

A size of a switch cell using a 65 nm-node core transistor is 1.4 μm×0.52 μm (a height of a switch cell=1.4 μm), and therefore a size (height) of a logic cell needs to be at least 32×1.4=44.8 μm.

On the other hand, as illustrated in FIG. 10, when Nr=3, (Nr+4)×0.24 μm=1.68 μm is established with respect to one switch cell. Therefore, a size (height) of a logic cell necessary for ensuring a wiring space needs to be at least 32×1.68=53.8 μm. Thereby, in an upper region and a lower region of a crossbar, a space of 53.8−44.8=9 μm (20% in a height (y) direction of the logic cell) can be ensured on a substrate.

However, as described above, in an upper region and a lower region of a resistance change element in a logic cell, a control line and a power supply line to a write control transistor of a crossbar are highly densely wired in a wiring layer close to a silicon substrate, resulting in a dead space where it is difficult to dispose a transistor.

On the other hand, as illustrated in FIG. 12, four look up tables are divided into two parts, and two look up tables are disposed in each logic unit (e.g. S=2, T=2). Further, a memory crossbar switch of a 2×32 size is disposed by being distributed at 3 locations. Thereby, in FIG. 12, a signal line does not come or go between logic memory units, and therefore (1+4)×0.24 μm=1.2 μm may be ensured as a wiring space for one switch cell in a height direction. Therefore, a minimum size (height) of a logic cell necessary for ensuring a wiring space is 32×1.2 μm=38.4 μm (<44.8 μm), and therefore a dead space where it is difficult to dispose a transistor is not generated.

### Third Example Embodiment

As illustrated in FIG. 12, when a logic unit is disposed by distribution in a logic cell, a difference in signal line length between the logic unit 310-1 located on a side close to the IMUX 330 and the logic unit 310-2 located on a far side increases. Therefore, even when the same logical operation is executed, an operation frequency is delayed when a critical path for an operation passes through the logic unit 310-2, compared with when passing through 310-1.

Therefore, when logical operation information is mapped for the logic memory units 320-1 to 320-Nr and a switch of the IMUX 330, a logical operation preferably uses preferentially a logic unit on a side close to the IMUX 330. The mapping represents that a resistance change element is written and a logical operation circuit is configured on a reconfigurable circuit. Thereby, an operation frequency can be increased, compared with a mapping pattern where allocation is made to a logic unit at random.

A direction of an arrow in the figures indicates one example and does not limit a direction of a signal between blocks.

A part or the whole of the respective example embodiments described above can be also described as the following supplementary notes. Note that the following supplementary notes do not limit the present invention in any way.

### [Supplementary Note 1]

A reconfigurable circuit including:

a logic memory unit including a resistance change element and being disposed by distribution into at least two units;

a logic unit that refers to the logic memory unit and executes a logical operation; and

a signal path switching unit that receives a result of the logical operation of the logic unit and outputs the result to an outside,

the logic memory unit and the signal path switching unit configuring a crossbar switch circuit and sharing write wiring to the resistance change element.

### [Supplementary Note 2]

The reconfigurable circuit according to supplementary note 1, wherein the logic unit is disposed by distribution into at least 2 units and each of the logic units disposed by distribution is connected to the associated logic memory unit.

### [Supplementary Note 3]

The reconfigurable circuit according to supplementary note 2, wherein

the crossbar switch circuit further includes a signal switching unit that outputs a control signal to the logic unit, and

the logic unit closest to the signal switching unit executes a logical operation among the logic units disposed by distribution into at least two units.

### [Supplementary Note 4]

The reconfigurable circuit according to any one of supplementary notes 1 to 3, wherein the logic unit and the signal path switching unit are adjacently disposed.

### [Supplementary Note 5]

The reconfigurable circuit according to any one of supplementary notes 1 to 4, wherein the logic memory units are disposed in an inversion symmetry manner to each other with respect to a predetermined direction.

### [Supplementary Note 6]

The reconfigurable circuit according to any one of supplementary notes 1 to 5, wherein

the signal path switching unit includes a switch cell including the resistance change element, and

the switch cell includes a first resistance change element and a second resistance change element, the elements being programmable to be in a low resistance state or a high resistance state, and at least one transistor; and one terminal of the first resistance change element, one terminal of the second resistance change element, and a source terminal or a drain terminal of the transistor are connected.

### [Supplementary Note 7]

The reconfigurable circuit according to supplementary note 6, wherein the first resistance change element and the second resistance change element each are a bipolar resistance change element and are disposed in such a way that resistance change polarities are opposed.

### [Supplementary Note 8]

The reconfigurable circuit according to supplementary note 6 or 7, wherein the first resistance change element and the second resistance change element each are an atom transfer element using an ion conductive layer.

### [Supplementary Note 9]

A reconfigurable circuit system, wherein reconfigurable circuits according to any one of supplementary notes 1 to 8 are disposed by being connected to one another in parallel.

### [Supplementary Note 10]

A method for operating a reconfigurable circuit, wherein

a logic unit refers to a logic memory unit including a resistance change element and being disposed by distribution into at least two units and executes a logical operation, and

a signal path switching unit receives a result of the logical operation of the logic unit and outputs the result to an outside,

the logic memory unit and the signal path switching unit configuring a crossbar switch circuit and sharing write wiring to the resistance change element.

### [Supplementary Note 11]

The method for operating a reconfigurable circuit according to supplementary note 10, wherein the logic unit is disposed by distribution into at least 2 units and each of the logic units disposed by distribution is connected to the associated logic memory unit.

### [Supplementary Note 12]

The method for operating a reconfigurable circuit according to supplementary note 11, wherein

the crossbar switch circuit further includes a signal switching unit that outputs a control signal to the logic unit, and

the logic unit closest to the signal switching unit executes a logical operation among the logic units disposed by distribution into at least two units.

### [Supplementary Note 13]

The method for operating a reconfigurable circuit according to any one of supplementary notes 10 to 12, wherein the logic unit and the signal path switching unit are adjacently disposed.

### [Supplementary Note 14]

The method for operating a reconfigurable circuit according to any one of supplementary notes 10 to 13, wherein the logic memory units are disposed in an inversion symmetry manner to each other with respect to a predetermined direction.

### [Supplementary Note 15]

The method for operating a reconfigurable circuit according to any one of supplementary notes 10 to 14, wherein

the signal path switching unit includes a switch cell including the resistance change element, and

the switch cell includes a first resistance change element and a second resistance change element, the elements being programmable to be in a low resistance state or a high resistance state, and at least one transistor; and one terminal of the first resistance change element, one terminal of the second resistance change element, and a source terminal or a drain terminal of the transistor are connected.

### [Supplementary Note 16]

The method for operating a reconfigurable circuit according to supplementary note 15, wherein the first resistance change element and the second resistance change element each are a bipolar resistance change element and are disposed in such a way that resistance change polarities are opposed.

### [Supplementary Note 17]

The method for operating a reconfigurable circuit according to supplementary note 15 or 16, wherein the first resistance change element and the second resistance change element each are an atom transfer element using an ion conductive layer.

The present invention has been described with reference to the above-described example embodiments as exemplary examples. However, the present invention is not limited to the above-described example embodiments. In other words, the present invention is applicable with various forms which could be understood by those skilled in the art.

This application is based upon and claims the benefit of priority from Japanese patent application No. 2016-008495, filed on Jan. 20, 2016, the disclosure of which is incorporated herein in its entirety by reference.

### REFERENCE SIGNS LIST

1 Reconfigurable circuit

2 Logic unit

3 Logic memory unit

4 Signal path switching unit

10 Resistance change element

11 First wiring layer

12 Second wiring layer

13 Solid electrolytic layer

100a to 100i Switch cell

110 First resistance change element

120 Second resistance change element

111, 121 First electrode

112, 122 Second electrode

130 Selection transistor

131, 132 Diffusion layer

133 Gate electrode

200 Crossbar switch circuit

210a, 210b, 210c First control transistor

220a, 220b, 220c Second control transistor

230a, 230b, 230c Third control transistor

300, 300′, 300A Logic cell

300-1 First logic cell

300-2 Second logic cell

300-3 Third logic cell

300-4 Fourth logic cell

310 Logic unit

310-1 Logic unit

310-2 Logic unit

320 Logic memory unit

320-1 Logic memory unit

320-2 Logic memory unit

320-Nr Nrth logic memory unit

330 Input/output signal switching unit

340 Signal path switching unit

400 Look up table

401a to 401h Multiplexer

500 Highest density wiring region

600a, 600b Switch cell

What is claimed is:

1. A reconfigurable circuit comprising:
a logic memory unit that includes a resistance change element and is disposed by distribution into at least two units;
a logic unit that refers to the logic memory unit and executes a logical operation; and
a signal path switching unit that receives a result of a logical operation of the logic unit and outputs the result to an outside,
the logic memory unit and the signal path switching unit that configures a crossbar switch circuit and shares write wiring to the resistance change element.

2. The reconfigurable circuit according to claim 1, wherein the logic unit is disposed by distribution into at least 2 units and each of the logic units disposed by distribution is connected to the associated logic memory unit.

3. The reconfigurable circuit according to claim 2, wherein
the crossbar switch circuit further includes a signal switching unit that outputs a control signal to the logic unit, and
the logic unit closest to the signal switching unit executes a logical operation among the logic units disposed by distribution into at least two units.

4. The reconfigurable circuit according to claim 1, wherein the logic unit and the signal path switching unit are adjacently disposed.

5. The reconfigurable circuit according to any one of claims 1 to 4, claim 1, wherein the logic memory units are disposed in an inversion symmetry manner to each other with respect to a predetermined direction.

6. The reconfigurable circuit according to claim 1, wherein
the signal path switching unit includes a switch cell that includes the resistance change element, and
the switch cell includes a first resistance change element and a second resistance change element, being programmable to be in a low resistance state or a high resistance state, and at least one transistor; and one terminal of the first resistance change element, one terminal of the second resistance change element, and a source terminal or a drain terminal of the transistor are connected.

7. The reconfigurable circuit according to claim 6, wherein the first resistance change element and the second resistance change element each are a bipolar resistance change element and are disposed in such a way that resistance change polarities are opposed.

8. The reconfigurable circuit according to claim 6, wherein the first resistance change element and the second resistance change element each are an atom transfer element using an ion conductive layer.

9. A reconfigurable circuit system comprising the reconfigurable circuits according to claim 1 that is disposed by being connected to one another in parallel.

10. A method for operating a reconfigurable circuit, comprising:
by a logic unit, referring to a logic memory unit including a resistance change element and being disposed by distribution into at least two units, and executing a logical operation; and
by a signal path switching unit, receiving a result of a logical operation of the logic unit, and outputting the result to an outside,
the logic memory unit and the signal path switching unit configuring a crossbar switch circuit and sharing write wiring to the resistance change element.

11. The method for operating a reconfigurable circuit according to claim 10, wherein the logic unit is disposed by distribution into at least 2 units and each of the logic units disposed by distribution is connected to the associated logic memory unit.

12. The method for operating a reconfigurable circuit according to claim 11, wherein
the crossbar switch circuit further includes a signal switching unit that outputs a control signal to the logic unit, and
the logic unit closest to the signal switching unit executes a logical operation among the logic units disposed by distribution into at least two units.

13. The method for operating a reconfigurable circuit according to claim 10, wherein the logic unit and the signal path switching unit are adjacently disposed.

14. The method for operating a reconfigurable circuit according to claim 10, wherein the logic memory units are disposed in an inversion symmetry manner to each other with respect to a predetermined direction.

15. The method for operating a reconfigurable circuit according to claim 10, wherein
the signal path switching unit includes a switch cell including the resistance change element, and
the switch cell includes a first resistance change element and a second resistance change element, being programmable to be in a low resistance state or a high resistance state, and at least one transistor; and one terminal of the first resistance change element, one terminal of the second resistance change element, and a source terminal or a drain terminal of the transistor are connected.

16. The method for operating a reconfigurable circuit according to claim 15, wherein the first resistance change element and the second resistance change element each are a bipolar resistance change element and are disposed in such a way that resistance change polarities are opposed.

17. The method for operating a reconfigurable circuit according to claim 15, wherein the first resistance change element and the second resistance change element each are an atom transfer element using an ion conductive layer.
